(19) United States
(12) Patent Application Publication
(10) Pub. No.: US 2005/0087872 A1
(43) Pub. Date: Apr. 28, 2005

(54) Wiring structure of semiconductor device and method of manufacturing the same

(76) Inventor: Kazuhide Abe, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/766,739

(22) Filed: Jan. 29, 2004

(30) Foreign Application Priority Data
Oct. 28, 2003 (JP) 367951/2003

(51) Int. Cl. H01L 23/48

(52) U.S. Cl. 257/751; 257/754

(57) ABSTRACT

The wiring structure of a semiconductor device of the invention enhances the dielectric strength of the wirings and reduces the capacitance across the wirings, by preventing a diffusion of the wiring material. The wiring structure includes a first insulating film, plural wiring films, plural barrier films, and plural cap films. The first insulating film has plural grooves formed thereon, and has an interface in the horizontal direction between the adjoining grooves. The wiring films are formed to protrude from the interface each by the grooves of the first insulating film. The barrier films are formed on the bottoms of the wiring films, and also on side faces of the wiring films to a height exceeding the interface. The cap films are formed at least on the upper faces of the wiring films, and are separated each by the grooves.

### BACKGROUND OF THE INVENTION

1. Field of the Invention

The present invention relates to a wiring structure of a semiconductor device and a method of the same.

2. Description of the Related Art

The orientation for the microstructure of a semiconductor device makes the influence of the RC delay (signal delay by resistances and capacitances) prominent, and the RC delay is a significant obstacle against the orientation for the high speed of the semiconductor device. In order to reduce the resistances of the wirings and the capacitances across the wirings, the wirings using copper Cu instead of aluminum alloy are introduced in the semiconductor device with the wiring breadth 0.25 μm or less. Since the dry etching is difficult to use in the formation of the wirings using Cu in general, the Damascene method is used which deposits Cu in wiring grooves formed on an insulating film, and then flattens. As an example, JP-A 10-270448 (page 2, FIG. 3), JP-A 2001-358105 (page 4-6, FIG. 2), JP-A 6-120219 (page 2-3, FIG. 2), JP-A 10-261635 (page 3-6, FIG. 1), JP-A 10-189590 (page 5-6, FIG. 10) and JP-A 2002-329780 (page 15, FIG. 20) disclose the structure of Cu wiring films formed by the Damascene method.

In the Cu wiring structure disclosed in JP-A 10-270448 and JP-A 2001-358105, plural wiring grooves are formed on a first silicon insulating film (silicon oxide film). In these grooves, Cu wiring films are formed through barrier films that prevent Cu from being oxidized and diffusing. The Cu wiring films and the barrier films are flattened to be flush with the interface of the first insulating film.

In the Cu wiring structure disclosed in JP-A 6-120219 and JP-A 10-261635, the Cu wiring films are embedded in the wiring grooves formed on the first insulating film through the barrier films, to be shallow compared with the depth of the wiring grooves. On the Cu wiring films, cap films made of a metal and a nitride film are embedded which prevent Cu from being oxidized and diffusing.

In the Cu wiring structure disclosed in JP-A 10-189590, the Cu wiring films are embedded in the wiring grooves formed on the first insulating film through the barrier films. The barrier films are formed to a height to be flush with the upper ends of the wiring grooves, and the Cu wiring films are protruded in a convex form from the wiring grooves. Further, a second insulating film (oxide film) is formed on the whole surface to overlie the Cu wiring films protruding from the wiring grooves.

In the Cu wiring structure disclosed in JP-A 2002-329780, the Cu wiring films are embedded in the wiring grooves formed on the first insulating film through the barrier films. The Cu wiring films and the barrier films protrude in a convex form from the wiring grooves. The cap films are formed to entirely cover the protruding parts of the Cu wiring films and the barrier films.

In the Cu wiring structure disclosed in JP-A 10-270448 and JP-A 2001-358105, the upper faces of the Cu wiring films being a leakage source of the wiring material are continuous with the interface of the first insulating film being a path of a leakage current. Therefore, Cu ions of the wiring material diffuse from the upper edges of the Cu wiring films through the interface of the first insulating film, thus making flows of the leakage current, or Cu hillocks are expanded from the upper edges of the Cu wiring films through the interface of the first insulating film, thus producing a possibility of electrically short-circuiting the wirings.

In the Cu wiring structure disclosed in JP-A 6-120219 and JP-A 10-261635, the upper faces of the Cu wiring films being a leakage source of the wiring material is located lower than the interface of the first insulating film being a path of a leakage current, that is, the leakage source of the wiring material and the path of a leakage current are separated above and below. Accordingly, it is necessary to deepen the wiring grooves by the film thickness of the cap films being embedded in the wiring grooves, which increases the aspect ratio of the wiring grooves accompanied with the micro-processing of the wiring breadth, thus producing a possibility of making the formation of the wiring films further difficult. Further, it is necessary to adjust the amount of recess of the Cu wiring films according to a required film thickness of the cap films, however it is very difficult to precisely control the amount of recess of the Cu wiring films in a pattern having a wide variety of breadths and densities of the wirings. This causes that the thickness of the Cu wiring films is not made uniform in a wafer, to consequentially disperse the resistances of the wirings.

In the Cu wiring structure disclosed in JP-A 10-189590, the interface of the second insulating film and the barrier films is in contact with the Cu wiring films. Accordingly, there is a possibility that Cu ions diffuse from the Cu wiring films through this interface, and Cu hillocks expand.

In the Cu wiring structure disclosed in JP-A 2002-329780, the upper edges of the Cu wiring films being a leakage source of the wiring material and the interface of the first insulating film being a path of a leakage current are separated in the vertical direction. However, the cap films having a high dielectric constant are formed on the whole surface, which increases the capacitances across the interlayer wirings in a multi-layered wiring structure, thus leading to an obstacle against the high speed performance of a semiconductor device.

In the Cu wiring structure disclosed in JP-A 10-189590 and JP-A 2002-329780, while thinning the film thickness of the first insulating film so as to make the upper face of the first insulating film lower than the upper faces of the Cu wiring films, there is a possibility that part of the Cu wiring films are shaved off, which causes dispersions of the wiring resistances.

### SUMMARY OF THE INVENTION

The present invention has been made in view of the above problems, and an object of the invention is to enhance the dielectric strength of the wirings and to reduce the capacitance across the wirings by preventing a diffusion of the wiring material, in the wiring structure of a semiconductor device.

Another object of the invention is to enhance the dielectric strength of the wirings and to restrain dispersions of the resistances of the wiring films by preventing a diffusion of the wiring material, in the wiring structure of a semiconductor device.

According to one aspect of the invention, the wiring structure includes a first insulating film, plural wiring films, plural barrier films, and plural cap films. The first insulating film has plural grooves formed thereon. And, the first insulating film has an interface in the horizontal direction between the adjoining grooves. The wiring films are formed to protrude from the interface each by the grooves of the first insulating film. The barrier films are formed on the bottoms of the wiring films and are also on the side faces of the wiring films to a height exceeding the interface. The cap films are formed at least on the upper faces of the wiring films, and are separated each by the grooves.

According to another aspect of the invention, the method of manufacturing a wiring structure of a semiconductor device includes the steps of: forming the plural grooves on the first insulating film, forming the barrier films and the wiring films in order on the first insulating film, flattening the wiring films and the barrier films until the first insulating film is exposed, and leaving the wiring films and the barrier films only in the grooves, after flattening the wiring films and the barrier films, forming cap films on a whole surface, removing the cap films so as to leave the cap films at least on the wiring films and the barrier films, and thinning the first insulating film in the parts having the cap films removed and protruding the wiring films and the barrier films from the interface of the first insulating film of the thinned parts.

In the wiring structure of this invention, since the edges of the upper faces of the wiring films being a leakage source of the wiring material are separated in the vertical direction from the interface of the first insulating film being the path of a leakage current by the wiring material, even if the wiring material is leaked from the wiring films, it is difficult to arrive at the interface of the first insulating film being the path of a leakage current, which restrains the wring material from diffusing. Further, the cap films are separated each by the grooves, and even if a material of a high dielectric constant is used for the cap films, the wiring structure is able to repress the increase of the capacitance across the wiring films. Thus, the wiring structure of the invention enhances the dielectric strength of the wirings and reduces the capacitances across the wirings.

In the method of manufacturing the wiring structure of the invention, since the edges of the upper faces of the wiring films being a leakage source of the wiring material are separated in the vertical direction from the interface of the first insulating film being the path of a leakage current by the wiring material, even if the wiring material is leaked from the wiring films, it is difficult to arrive at the interface of the first insulating film being the path of a leakage current, thereby restraining the wring material from diffusing. And, while leaving the cap films at least on the wiring films and the barrier films, the first insulating film is thinned using the cap films as the mask; therefore in the thinning of the first insulating film, the method prevents part of the wiring films from being removed, and restrains the resistances of the wiring films from dispersing.

### BRIEF DESCRIPTION OF THE DRAWINGS

FIG. 1 is a section for explaining the method of manufacturing the wiring structure of a semiconductor-device relating to the first embodiment;

FIG. 2 is a section for explaining the method of manufacturing the wiring structure of a semiconductor device relating to the first embodiment;

FIG. 3 is a section for explaining the method of manufacturing the wiring structure of a semiconductor device relating to the first embodiment;

FIG. 4 is a section for explaining the method of manufacturing the wiring structure of a semiconductor device relating to the first embodiment;

FIG. 5 is a section for explaining the method of manufacturing the wiring structure of a semiconductor device relating to the first embodiment;

FIG. 6 is a section for explaining the method of manufacturing the wiring structure of a semiconductor device relating to the first embodiment;

FIG. 7 is a section for explaining the method of manufacturing the wiring structure of a semiconductor device relating to the first embodiment;

FIG. 8 is a section for explaining the method of manufacturing the wiring structure of a semiconductor device relating to the first embodiment;

FIG. 9 is a section for explaining the method of manufacturing the wiring structure of a semiconductor device relating to the first embodiment;

FIG. 10 is a section for explaining the method of manufacturing the wiring structure of a semiconductor device relating to the first embodiment;

FIG. 11 is a section for explaining the method of manufacturing the wiring structure of a semiconductor device relating to the second embodiment;

FIG. 12 is a section for explaining the method of manufacturing the wiring structure of a semiconductor device relating to the second embodiment;

FIG. 13 is a section for explaining the method of manufacturing the wiring structure of a semiconductor device relating to the third embodiment;

FIG. 14 is a section for explaining the method of manufacturing the wiring structure of a semiconductor device relating to the third embodiment;

FIG. 15 is a section for explaining the method of manufacturing the wiring structure of a semiconductor device relating to the third embodiment;

FIG. 16 is a section for explaining the method of manufacturing the wiring structure of a semiconductor device relating to the third embodiment;

FIG. 17 is a section for explaining the method of manufacturing the wiring structure of a semiconductor device relating to the third embodiment;

FIG. 18 is a section for explaining the method of manufacturing the wiring structure of a semiconductor device relating to the fourth embodiment;

FIG. 19 is a section for explaining the wiring structure of a semiconductor device relating to the first embodiment, when the wiring structure has a dishing;

FIG. 20 is a section for explaining the wiring structure of a semiconductor device relating to the first embodiment, when the cap films 106 are formed only on the upper faces of the wiring, films 105 and the barrier films 103;

FIG. 21 is a section for explaining the wiring structure of a semiconductor device relating to the third embodiment, when the cap films 301 are formed only on the upper faces of the wiring films 105 and the barrier films 103; and

FIG. 22 is a section for explaining the wiring structure of a semiconductor device relating to the fourth embodiment, when the cap films 301 are formed only on the upper faces of the wiring films 105 and the barrier films 103.

### DETAILED DESCRIPTION OF THE PREFERRED EMBODIMENTS

### (1) First Embodiment

[Structure]

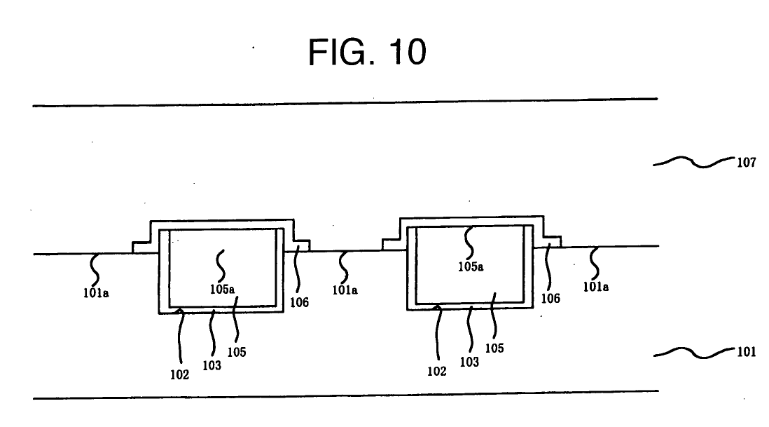

FIG. 10 is a section of the wiring structure relating to the first embodiment of the invention. This wiring structure includes a first insulating film 101, plural barrier films 103, plural wiring films 105, plural cap films 106, and a second insulating film 107. The insulating film 101 has plural grooves 102 formed thereon. The insulating film 101 also has an interface 101a as the upper face in the horizontal direction between the adjoining grooves 102. The wiring films 105 are formed in each of the grooves 102 to protrude in a convex form from the interface 101a. The barrier films 103 are formed on the bottoms of the wiring films 105, and are also formed on the sides of the wiring films 105 to a height exceeding the interface 101a. The cap films 106 are formed at least on the upper faces of the wiring films 105, and are separated each by the grooves 102. The second insulating film 107 is formed on the cap films 106 and the first insulating film 101.

[Manufacturing Method]

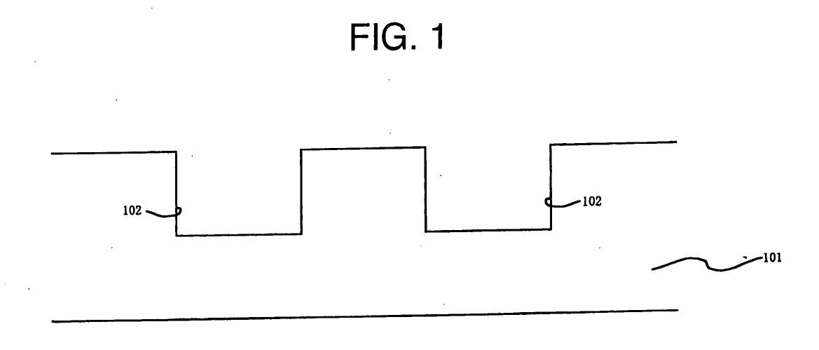

The manufacturing method of the wiring structure will be described with reference to FIG. 1 through FIG. 9.

As shown in FIG. 1, the insulating film 101 of 500 nm thick, made of silicon oxide SiO₂, is formed by the CVD method on a substrate (not illustrated) where semiconductor elements are formed. The plural grooves 102 are formed in programmed regions for wiring formation (regions where the wiring patterns are formed) by means of the photolithography and the etching. The grooves 102 each have the breadth 200 nm and the depth 350 nm, and the spacing between the adjoining grooves is 200 nm. The etching of the grooves 102 employs, for example, a magnetron-type Reactive Ion Etching (RIE) apparatus. The etching of the insulating film 101 can employ an etching apparatus that is appropriately selected among a magnetron-type cathode coupled etching apparatus, dual frequency excitation capacitive coupled plasma etching apparatus, and IPC (Inductive Coupled Plasma)-type etching apparatus. The etching gas used for the etching of the insulating film 101 is composed of, for example, octafluorocyclobutane C₄F₈, carbon monoxide CO, oxygen O₂, and argon Ar. The etching condition is set to, for example, gas flow rate C₄F₈/CO/O₂/Ar=14/50/5/30 sccm, RF power 1.5 kW, and chamber pressure 50 mTorr.

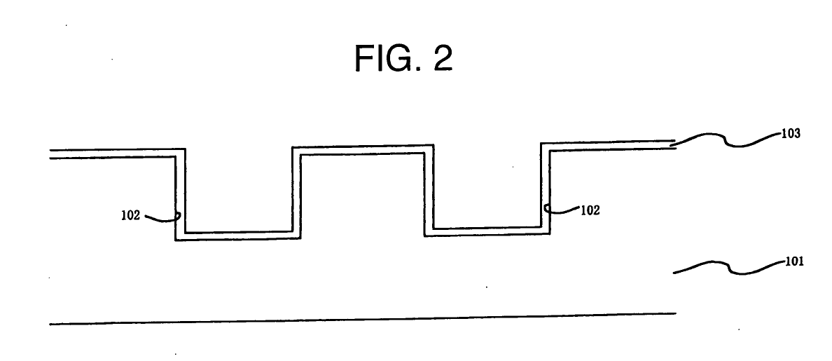

Next as shown in FIG. 2, the barrier films 103 of 50 nm thick, made of tantalum nitride TaₓN_{y}, are formed on the insulating film 101. Concretely, the barrier films 103 are formed on the inner face (bottom and side faces) of the grooves 102 of the insulating film 101 and on the surface of the insulating film 101. The formation of the barrier films 103 deposits tantalum nitride TaₓN_{y} by means of a highly directional sputtering, for example, using Ta for the target and mixed gas Ar/N₂ for the process gas, under the condition of the atmospheric pressure 3 mTorr, film formation temperature 150° C., and DC power 6 kW. Here, the barrier films 103 are not limited to tantalum nitride TaₓN_{y}, and the materials having the similar function that prevents a diffusion of Cu may be used, such as: Ta, TaₓSi_{y}N_{z}, TiₓN_{y}, TiₓSi_{y}N_{z}, WₓN_{y}, WₓSi_{y}N_{z}.

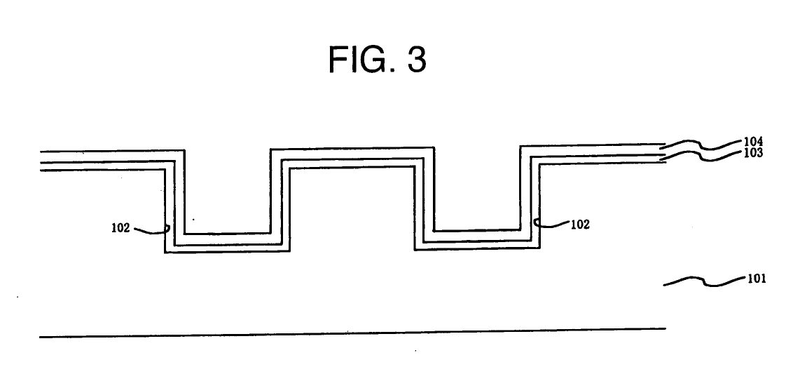

Next as shown in FIG. 3, Cu seed films 104 of 150 nm thick are formed to function as the seed for the plating film on the surface of the barrier films 103. The formation of the Cu seed films 104 deposits Cu by means of a highly directional sputtering, for example, using Cu for the target and Ar for the process gas, under the condition of the atmospheric pressure 2 mTorr, film formation temperature 30° C., and DC power 12 kW. The Cu seed films 104 may be Cu or alloy containing Cu as the principal ingredient.

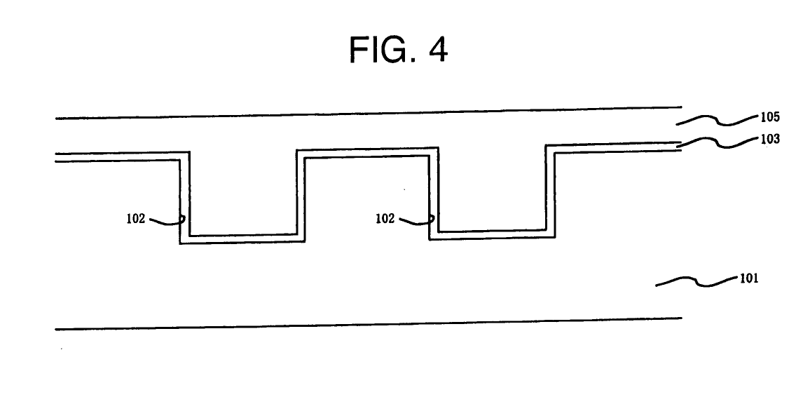

Next as shown in FIG. 4, the wiring films 105 made of Cu are deposited on the surface of the Cu seed films 104 by means of the electrolytic plating. The deposition of the wiring films 105 needs a thickness that sufficiently embeds the grooves 102 or more, however in this case, the wiring films 105 are deposited to the height of some 100 nm from the surface of the insulating film 101. The electrolytic plating uses a plating solution containing, for example, copper sulfate CuSO₄.5H₂O being the source to precipitate Cu compositions, sulfate H₂SO₄ for enhancing the conductivity, chlorine Cl for accelerating the solution of the glossiness and solubility anode (for example, Cu containing phosphor) of the high current density part, and additive agent for enhancing the embedding property and so forth. The electrolytic plating is carried out, using the above plating solution as an example under the condition of the solution temperature 25° C. and a constant current, while switching the current density at two stages. The current density is switched into, for example, the low current density 0.2 A/dm² at the first stage, and the high current density 2 A/dm² at the second stage. If the electrolytic plating is carried out with the high current density only, the plating films (wiring films 105) will close at the entrances of the grooves 102 being fine patterns, which leads to a possibility of forming voids; on the other hand, if the electrolytic plating is carried out with the low current density only, the depositing speed of the wiring films 105 is very slow, which requires a long time to embed the grooves 102. This is the reason of changing the current density into two levels. In the descriptions hereunder, the wiring films are called the wiring films 105, including the Cu seed films.

After processing the electrolytic plating of the wiring films 105, the thermal treatment is carried out in the furnace under, for example, the temperature 100 to 350° C., for 1 to 300 minutes in the ambient atmosphere of the mixed gas of nitrogen N₂ and hydrogen H₂. Or, the thermal treatment may be carried out with the substrate mounted on a hot plate. This thermal treatment prompts the growth of fine Cu crystal grains of the wiring films 105, and at the same time stabilizes the hardness, crystallinity, and resistivity, etc., of the films.

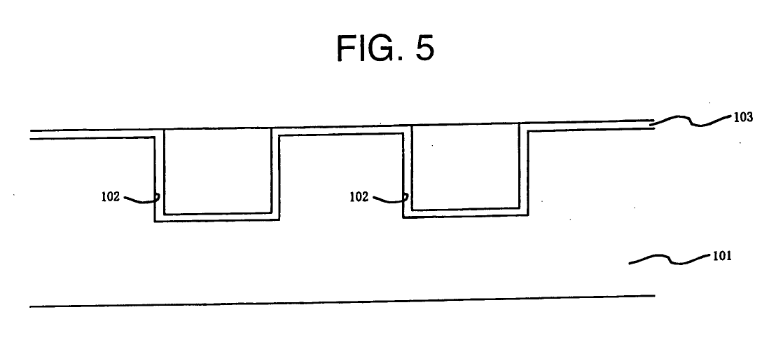

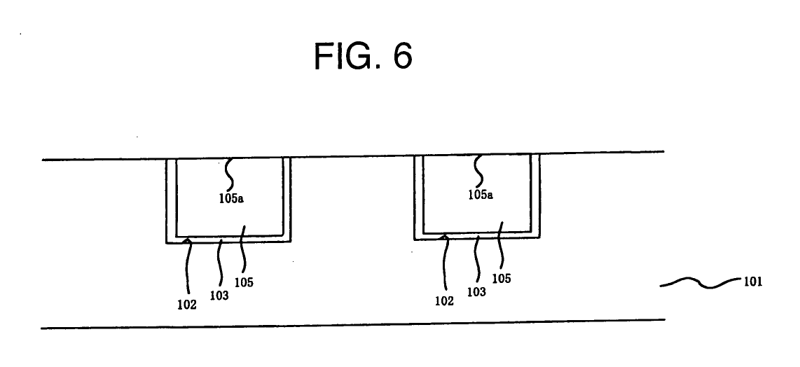

Next as shown in FIG. 5 and FIG. 6, the wiring films 105 and the barrier films 103 are polished by means of the CMP method to flatten the films thereof. More in detail, the wiring films 105 and the barrier films 103 are removed so as to expose the insulating film 101, thus leaving the wiring films 105 and the barrier films 103 only in the grooves 102. As the result, the upper faces of the wiring films 105 and the barrier films 103 become flush with the surface of the insulating film 101. Here, 105a represents the upper faces of the wiring films 105.

The polishing by the CMP includes the polishing at two stages, for example. At the first stage, the wiring films 105 are polished and removed, using the barrier films 103 as the stopper, till exposing the surfaces of the barrier films 103 overlying the surface of the insulating film 101 (FIG. 5). The first stage uses the solution containing silica as polishing particles with hydrogen peroxide H₂O₂ added as Cu complex formation accelerator, as slurry. And, the polishing uses a laminated structure of a bonded fabric and independent foam for the polishing pad, and sets the condition to: slurry flow rate 200 ml/min, polishing load 2 psi, carrier head revolution speed 120 rpm, and table revolution speed 120 rpm. Next at the second stage, the barrier films 103 overlying the surface of the insulating film 101 are removed, using the insulating film 101 as the stopper (FIG. 6). The second stage also uses the solution containing silica as polishing particles with hydrogen peroxide H₂O₂ added, as slurry. And, the polishing also uses a laminated structure of a bonded fabric and independent foam for the polishing pad, and sets the condition to: slurry flow rate 200 ml/min, polishing load 2 psi, carrier head revolution speed 80 rpm, and table revolution speed 80 rpm.

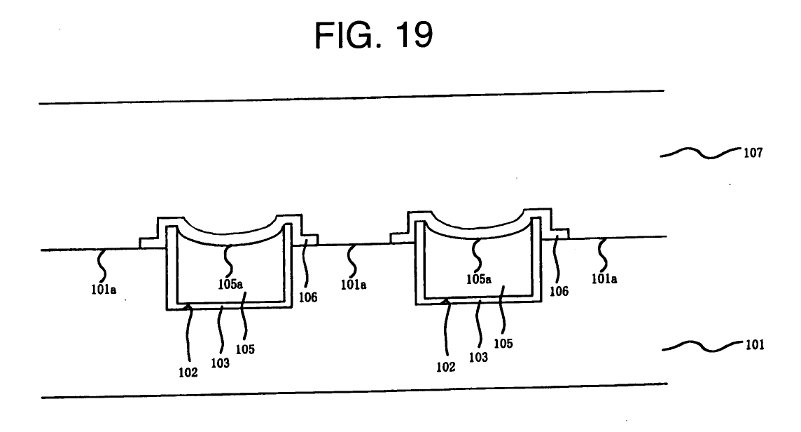

In the flattening of the wiring films 105 and the barrier films 103, idealistically the upper faces of the wiring films 105 are coincident with the upper faces of the barrier films 103. In practice however, when removing the barrier films 103 as shown in FIG. 6 (the polishing at the second stage), there occurs a dishing as shown in FIG. 19, such that the wiring films 105 inside the grooves 102 are polished slightly deeper than the barrier films 103. As the result, the centers of the upper faces 105a of the wiring films 105 are recessed by 5 nm to 10 nm against the upper faces of the barrier films 103. Even in this case, the upper faces 105a of the wiring films 105 being a leakage source of Cu ions and Cu hillocks are protruded higher than the interface 101a of the insulating film 101 by the thinning of the insulating film 101, described later.

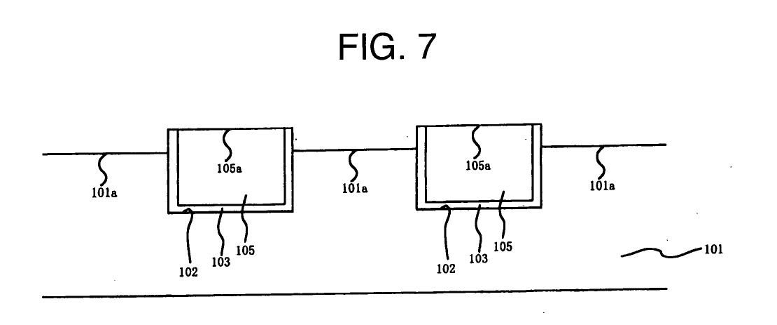

Next as shown in FIG. 7, the insulating film 101 is removed from the surface, for example, by 50 nm to thin the film. The thinning of the insulating film 101 may use the polishing by the CMP, or may use the etch-back method, using fluorine acid (0.3% HF, etc.). The barrier films 103 and the wiring films 105 are protruded in a convex form from the surface of the insulating film 101, by the thinning of the insulating film 101.

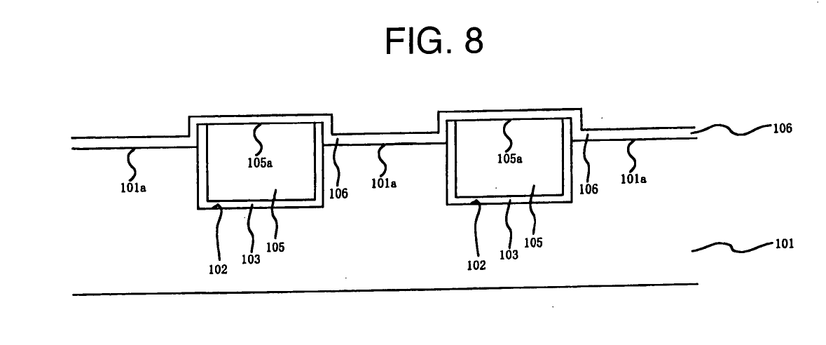

Next as shown in FIG. 8, the cap films 106 of 50 nm thick, made of tantalum Ta, are deposited to cover the surface of the insulating film 101 and the wiring films 105. The cap films 106 are formed by means of a highly directional sputtering, for example, using Ta for the target and argon Ar for the process gas, under the condition of the atmospheric pressure 3 mTorr, film formation temperature 150° C., and DC power 6 kW. The cap films 106 desirably contain metallic elements to enhance the adherence to the wiring films 105 and the barrier films 103. To improve the adherence to the wiring films 105 and the barrier films 103 will restrain Cu ions from diffusing, and will also restrain Cu hillocks from being created. Further, by separating the upper faces 105a of the wiring films 105 being a leakage source of a diffusion of Cu such as the diffusion of Cu ions and the expansion of Cu hillocks from the interface 101a of the insulating film 101 being a path of a leakage current between the wiring films 105 in the vertical direction, if Cu diffuses on the upper faces of the barrier films 103, it is difficult to arrive at the interface 101a of the insulating film 101, which will repress a leakage current and prevent a short-circuiting between the wiring films 105.

Here, the formation of the cap films 106 may use the following conductive film: a metal film containing tantalum Ta as the principal composition such as TaₓN_{y}, TaₓSi_{y}N_{z}, a metal film containing titanium Ti as the principal composition such as TiₓN_{y}, TiₓSi_{y}N_{z}, a metal film containing tungsten W as the principal composition such as WₓN_{y}, WₓSi_{y}N_{z}. Further, the formation of the cap films 106 may use SiₓN_{y}, SiₓO_{y}N_{z}, SiₓC_{y}, or an insulating film containing SiₓC_{y} as the principal composition. If the cap films 106 are formed with an insulating film, the sides of the upper faces of the barrier films 103 that are likely to diffuse Cu ions and to create Cu hillocks will be covered with the insulating film, which makes it possible to further repress a leakage current between the wiring films and repress an electric short-circuiting between the wirings.

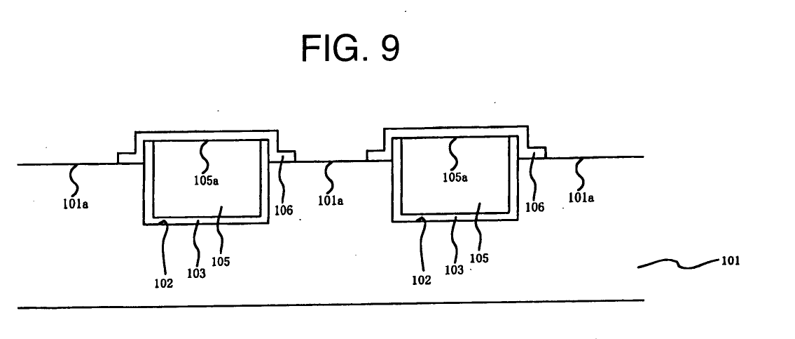

Next as shown in FIG. 9, the cap films 106 located between the wiring films 105, namely, located on the interface 101a of the insulating film 101 are removed by means of the photolithography and the etching technique, thereby separating the cap films 106 each by the wiring films 105. Thereafter, as shown in FIG. 10, the insulating film 107 of 700 nm thick, made of silicon oxide SiO₂, is deposited by means of the CVD method.

[Function and Effect]

According to the wiring structure of this embodiment, the wiring films 105 and the barrier films 103 are formed to protrude from the grooves 102 in a convex form, since the edges of the upper faces 105a of the wiring films 105 being a leakage source of the wiring material Cu are separated in the vertical direction from the interface 101a being a path of a leakage current by the wiring material, even if the wiring material Cu is leaked from the wiring films 105, it is difficult to arrive at the interface 101a being the path of a leakage current, which restrains the wring material Cu from diffusing.

If the cap films 106 are formed on the whole surface with a material of a high relative dielectric constant, it will lead to a problem that the capacitance across the wirings increases. The capacitances across the interlayer wirings increase especially in a multi-layered wiring structure, which leads to a possibility that causes delays of signals. In contrast to this, if the cap films 106 are separated each by the grooves 102 as in this embodiment, it will reduce the relative dielectric constant in the total of the cap films 106 and the insulating film 107 being the interlayer insulating material, that is, the effective relative dielectric constant, and it will restrain the capacitances across the interlayer wirings from increasing. Especially, when the cap films 106 are formed with SiₓN_{y} of the relative dielectric constant 7.0, and the insulating film 107 is formed with silicon oxide SiO₂ of the relative dielectric constant 4.2, the relative dielectric constant of the cap films 106 is significantly larger than that of the insulating film 107; accordingly, a decrease of the volume of the cap films 106 will significantly reduce the capacitances across the interlayer wirings.

In some cases, to reduce the capacitances across the wirings, silicon oxide SiO₂ having fluorine of a low relative dielectric constant doped (FSG film, relative dielectric constant about 3.5) is used as the material for the insulating film 107, and as the relative dielectric constant of the insulating film 107 becomes lower, the cap films 106 give higher influence to the effective dielectric constant. Therefore, the structure that separates the cap films 106 each by the grooves 102 as shown in this embodiment is effective in reducing the effective dielectric constant.

According to the wiring structure of a semiconductor device relating to this embodiment thus described, it is possible to enhance the dielectric strength across the wirings and to reduce the capacitance across the wirings by repressing a diffusion of the wiring material Cu.

In the process illustrated in FIG. 6, when the wiring films 105 and the barrier films 103 are polished and flattened by means of the CMP method, as shown in FIG. 19, there is a possibility that the centers of the upper faces 105a of the wiring films 105 are recessed by 5 nm to 10 nm against the upper faces of the barrier films 103. Even in such a case, since the upper faces 105a of the wiring films 105 being a leakage source of Cu ions and Cu hillocks are protruded higher than the interface. 101a of the insulating film 101 being a path of a leakage current, and the edges of the upper faces 105a of the wiring films 105 and the interface 101 a are separated in the vertical direction, Cu ions or Cu hillocks are difficult to arrive at the interface 101a of the insulating film 101 from the upper faces 105a of the wiring films 105.

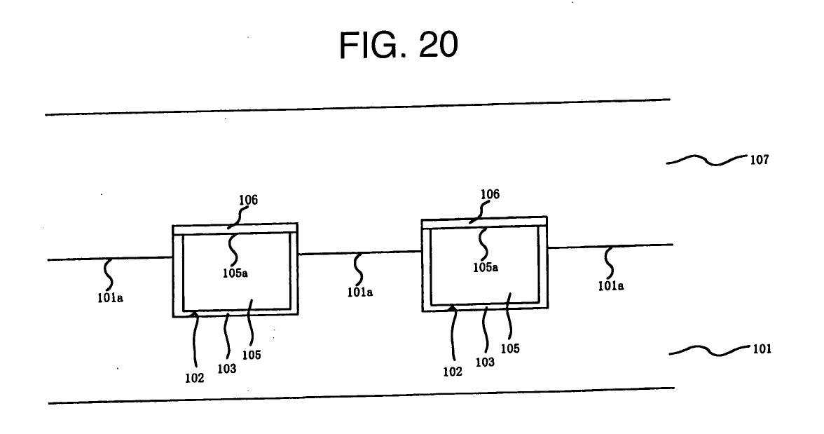

In the above embodiment, the cap films 106 are separated on the interface 101a; however as shown in FIG. 20, the cap films 106 may be formed to lie only on the upper faces of the wiring films 105 and the barrier films 103. If the cap films 106 are formed as shown in FIG. 20, and the material thereof is conductive, the distance between the adjoining cap films 106, that is, substantially the distance between the wirings will be expanded, which will further enhance the dielectric strength. And, if the cap films 106 are an insulating film of a high dielectric constant, it will further reduce the effective dielectric constant. There can be a case such that the cap films 106 are dislocated, and part of the upper faces of the barrier films 103 are not covered with the cap films 106; if the upper faces of the wiring films 105 are covered with the cap films 106, it will prevent the wiring films 105 from being oxidized, and there does not occur a problem.

### (2) Second Embodiment

[Structure]

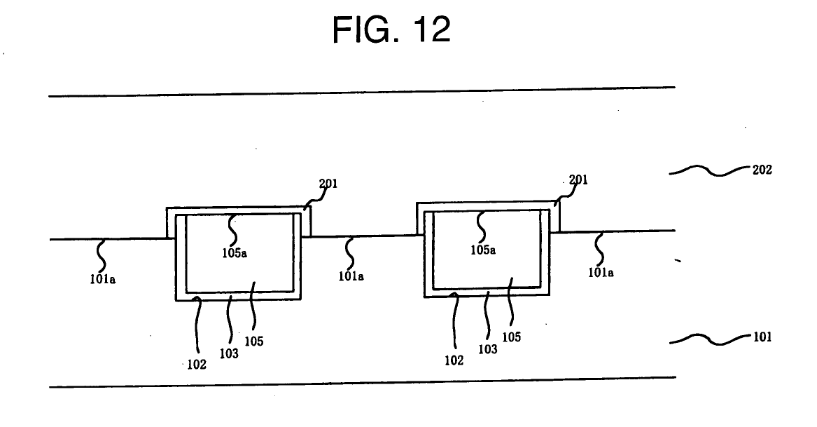

FIG. 12 is a section of the wiring structure relating to the second embodiment of the invention. This wiring structure includes a first insulating film 101, plural barrier films 103, plural wiring films 105, plural cap films 201, and a second insulating film 202. The insulating film 101 has plural grooves 102 formed thereon. The insulating film 101 also has an interface 101a as the upper face in the horizontal direction between the adjoining grooves 102. The wiring films 105 are formed in each of the grooves 102 of the insulating film 101 to protrude in a convex form from the interface 101a. The barrier films 103 are formed on the bottoms of the wiring films 105, and are also formed on the sides of the wiring films 105 to a height exceeding the interface 101a. The cap films 201 are formed selectively on protruded parts of the wiring films 105 and the barrier films 103 from the interface 101a. The second insulating film 107 is formed on the cap films 201 and the first insulating film 101.

[Manufacturing Method]

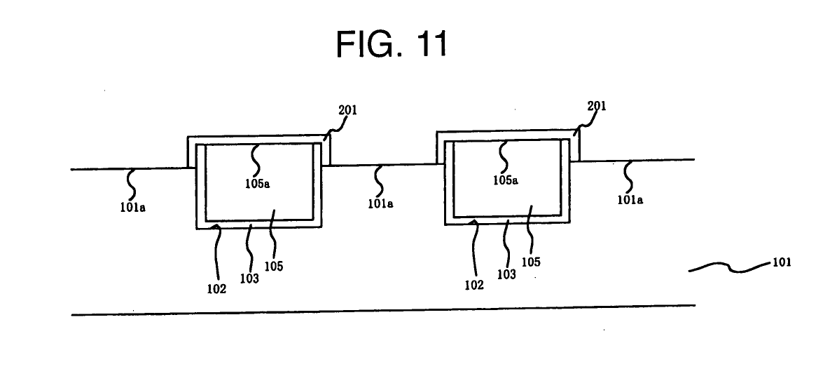

The manufacturing method of the wiring structure relating to the second embodiment will be described with reference to FIG. 11 and FIG. 12.

After passing the processes of FIG. 1 through FIG. 7 relating to the first embodiment, the cap films 201 of 30 nm thick, made of tungsten W, are formed selectively on the wiring films 105 and the barrier films 103 protruding in a convex form from the interface 101a. As the preliminary treatment for the formation of the cap films 201 with tungsten W, the thermal treatment is carried out in the atmosphere containing hydrogen gas H₂, which removes oxide films overlying the surfaces of the wiring films 105. The condition of this thermal treatment is set to, for example, substrate temperature 350° C., H₂ flow rate 1000 sccm, Ar flow rate 300 sccm, pressure 1 Torr, processing time 60 sec ˜300 sec. Following this thermal treatment, the substrate (state of wafer) is conveyed into the chamber for forming the tungsten W film without breaking the vacuum, where the cap films 201 of 30 nm thick, made of tungsten W, are selectively deposited. The condition of forming the tungsten W film is set to, for example, substrate temperature 200-300° C., WF₆ flow rate 5 sccm, H₂ flow rate 500 sccm, pressure 300 mTorr. The tungsten W being a metal is selectively deposited on the wiring films 105 and the barrier films 103 being metal films. More in detail, the tungsten W is selectively deposited on the upper faces of the wiring films 105 and on the upper and side faces of the barrier films 103. In this case, the preliminary treatment (thermal treatment) for forming the tungsten W film and the formation of the tungsten W film are carried out in separate chambers, however these processing may be carried out in the same chamber.

After selectively forming the cap films 201 on the wiring films 105 and the barrier films 103, the insulating film 202 of 700 nm thick, made of silicon oxide SiO₂, is deposited to cover the insulating film 101 and the cap films 201 by the CVD method, in the same manner as the first embodiment (FIG. 12).

[Function and Effect]

In the wiring structure relating to this embodiment, in the same manner as the first embodiment, since the upper faces 105a of the wiring films 105 being a leakage source of the wiring material Cu are separated in the vertical direction from the interface 101a being a path of a leakage current, even if the wiring material Cu is leaked from the wiring films 105, it is difficult to arrive at the interface 101a being the path of a leakage current, which restrains the wring material Cu from diffusing.

Since the upper faces 105a of the wiring films 105 are in contact with the cap films 201 made of metal, the wiring films 105 and the cap films 201 bear a satisfactory adhesion, which improves electro-migration resistance on the upper faces 105a. Thus, it is possible to suppress the leakage of the wiring material itself from the wiring films 105, and to further enhance the dielectric strength between the wiring films 105.

The insulating film 101 is directly adhered to the insulating 202 between the wiring films 105 without intervention of the cap films 201. To put the cap films 201 being metal films between the insulating film 101 and the insulating 202 will deteriorate the adhesion between the insulating film 101 and the insulating 202; however in this case, the insulating film 101 and the insulating 202 are directly adhered to each other, and the adhesion between the insulating film 101 and the insulating 202 can be improved.

In this embodiment, the cap films 201 made of tungsten W are formed selectively on the wiring films 105 and the barrier films 103, which makes the cap films 201 separate each by the grooves 102. Therefore, it is possible to omit the photolithography and the etching for separating the cap films each by the grooves 102, and to, simplify the manufacturing process.

### (3) Third Embodiment

The wiring structure relating to this embodiment intends to achieve another object of the invention. That is, in the Cu wiring structure as disclosed in JP-A 10-189590 and JP-A 2002-329780 in the Related Art, while thinning the film thickness of the first insulating film so as to make the upper face of the first insulating film lower than the upper faces of the Cu wiring films, there is a possibility that part of the Cu wiring films are shaved off, which causes dispersions of the wiring, resistances. Accordingly, the wiring structure of this embodiment intends to enhance the dielectric strength of the wirings by preventing a diffusion of the wiring material, and to repress dispersions of the resistances of the wiring films.

[Structure]

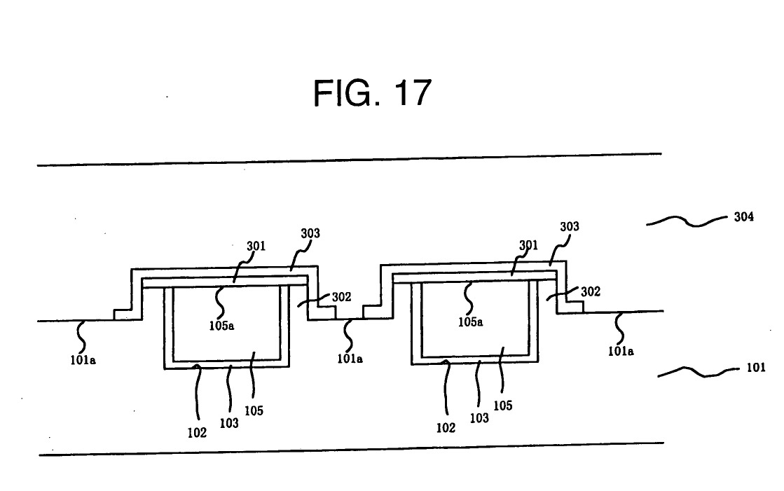

FIG. 17 is a section of the wiring structure relating to the third embodiment of the invention. This wiring structure includes a first insulating film 101 with plural protrusions 302 formed, plural barrier films 103, plural wiring films 105, plural first cap films 301, plural second cap films 303, and a second insulating film 304.

The insulating film 101 has plural grooves 102 formed thereon. The insulating film 101 also has an interface 101 a as the upper face in the horizontal direction between the adjoining grooves 102. Further, the insulating film 101 has the plural protrusions 302 formed to protrude from the interface 101a. The wiring films 105 are formed in each of the grooves 102 to protrude in a convex form from the interface 101a. The barrier films 103 are formed on the bottoms of the wiring films 105, and are also formed on the sides of the wiring films 105 to a height exceeding the interface 101a. The upper faces of the wiring films 105 and the barrier films 103 are formed to be substantially flush with the upper edges of the grooves 102. The cap films 301 are used as the etching mask in forming the protrusions 302 by etching the insulating film 101. The cap films 303 are formed to cover the cap films 301 and the protrusions 302. The insulating film 304 is formed to cover the cap films 303 and the insulating film 101.

Idealistically the upper faces of the wiring films 105 and the barrier films 103 are coincident with each other. In practice, as described in the first embodiment, when removing the barrier films 103 (the polishing at the second stage), there occurs a dishing such that the wiring films 105 inside the grooves 102 are polished slightly deeper than the barrier films 103. As the result, the centers of the upper faces 105a of the wiring films 105 are recessed by 5 nm to 10 nm against the upper faces of the barrier films 103. Even in this case, the upper faces 105a of the wiring films 105 being a leakage source of Cu ions and Cu hillocks are protruded higher than the interface 101a of the insulating film 101 by the thinning of the insulating film 101, described later.

[Manufacturing Method]

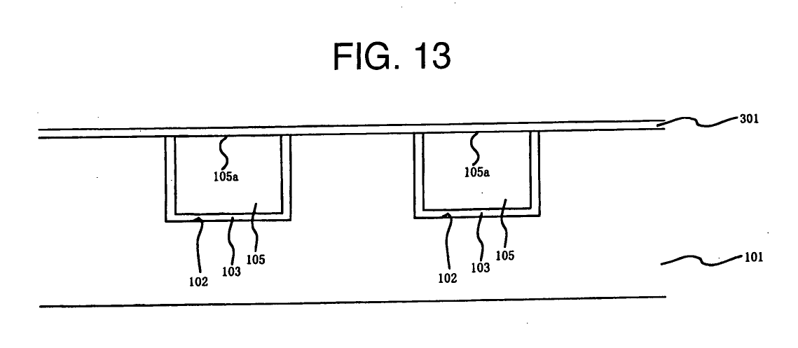

The manufacturing method of the wiring structure relating to the third embodiment will be described with reference to FIG. 13 through FIG. 17.

After passing the processes of FIG. 1 through FIG. 6 relating to the first embodiment, as shown in FIG. 13, the cap films 301 of 50 nm thick, made of titanium nitride TiₓN_{y}, are formed on the insulating film 101 having the wiring films 105 and the barrier films 103 embedded in the grooves 102. The cap films 301 may be made of an alloy mainly containing Ta such as Ta, TaₓN_{y}, TaₓSi_{y}N_{z}, an alloy mainly containing Ti such as TiₓSi_{y}N_{z}, or an alloy mainly containing W such as WₓN_{y}, WₓSi_{y}N_{z}, etc.

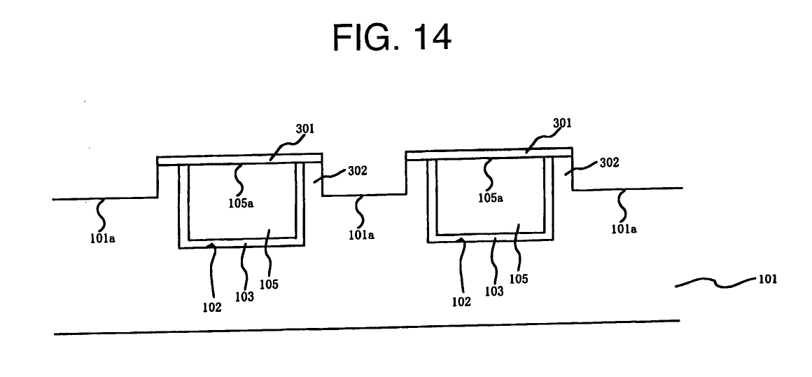

Next as shown in FIG. 14, the parts of the cap films 301 except for the areas surrounding the grooves 102 are removed by means of the photolithography and the etching, and the insulating film 101 underlying the parts having the cap films 301 removed is thinned. Thereby, the parts of the insulating film 101 left on the peripheries of the grooves 102 are formed into the protrusions 302. The condition of the etching (first etching) of the cap films 301 is as an example: chlorine Cl₂ and boron trichloride BCl₃ used as the etching gas, gas flow rate Cl₂/BCl₃=70/30 sccm, chamber pressure 15 mTorr, RF power 12 kW, and bias power 60 W. The condition of the etching (second etching) of the insulating film 101 is as an example: C₄F₈, CO, O₂, Ar used as the etching gas, gas flow rate C₄F₈/CO/O₂/Ar=14/50/5/30 sccm, RF power 1.5 kW, and chamber pressure 50 mTorr.

Here, the etching of the cap films 301 and the etching of the insulating film 101 are carried out separately, however the thinning of the insulating film 101 may be carried out together with the etching of the cap films 301 (first etching), and thereby the second etching may be omitted. The first etching is the chemical etching to mainly remove the cap films 301, however it also contains the compositions for the physical etching in the sputtering of the surface, in addition to the compositions for the chemical etching. Therefore, it is possible in the first etching to excessively etch the cap films 301 as well as thin the insulating film 101 by the physical etching.

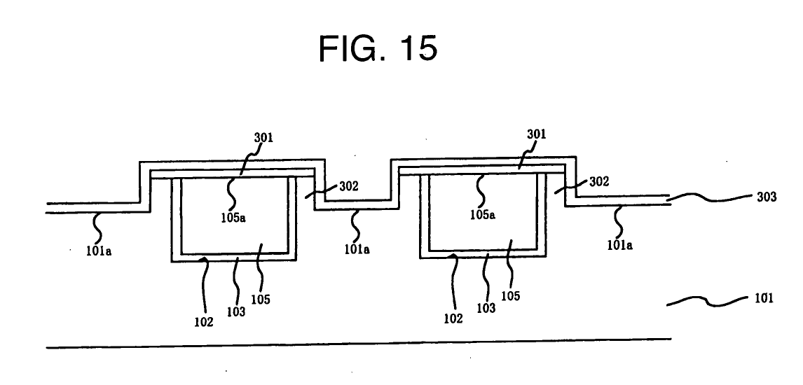

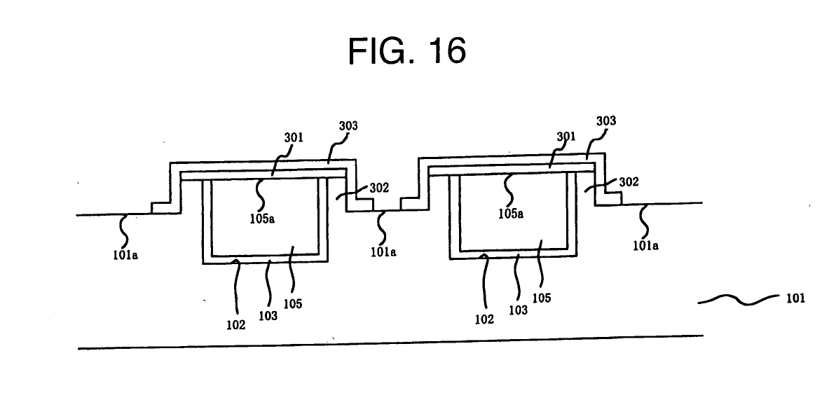

Next as shown in FIG. 15, the cap films 303 of 50 nm thick made of silicon nitride SiₓN_{y} are deposited by means of the CVD. Next as shown in FIG. 16, the cap films 303 are separated each by the grooves 102 (each by the protrusions 302). Thereafter, as shown in FIG. 17, the insulating film 304 of 700 nm thick made of silicon oxide SiO₂ is deposited on the cap films 303 by the CVD method.

[Function and Effect]

Also in the wiring structure relating to this embodiment, since the edges of the upper faces 105a of the wiring films 105 being a leakage source of the wiring material Cu are separated in the vertical direction from the interface 101a being a path of a leakage current by the wiring material, even if the wiring material Cu is leaked from the wiring films 105, it is difficult to arrive at the interface 10la being the path of a leakage current, which restrains the wring material Cu from diffusing to thereby enhance the dielectric strength of the wirings.

Also in this embodiment, since the cap films 301 and 303 are separated each by the grooves 102, it is possible to reduce the effective relative dielectric constant and repress the capacitances across the interlayer wirings.

In this embodiment, the insulating film 101 is thinned in the state that the wiring films 105 are covered with the cap films 301. Therefore, it is possible, in the thinning of the insulating film 101, to prevent the wiring films 105 from decreasing the volume thereof by being polished in the polishing process using the CMP method. Thereby, it is possible to restrain dispersions of the resistances of the wiring films 105.

In case of thinning the insulating film 10i through the HF processing, there is an apprehension that the films made of Ta generally used for the barrier films 103 are etched. However, in case of carrying out the etching as in this embodiment, in the state that the wiring films 105 and the barrier films 103 are covered with the cap films 301, there cannot be an apprehension that the films made of Ta are etched.

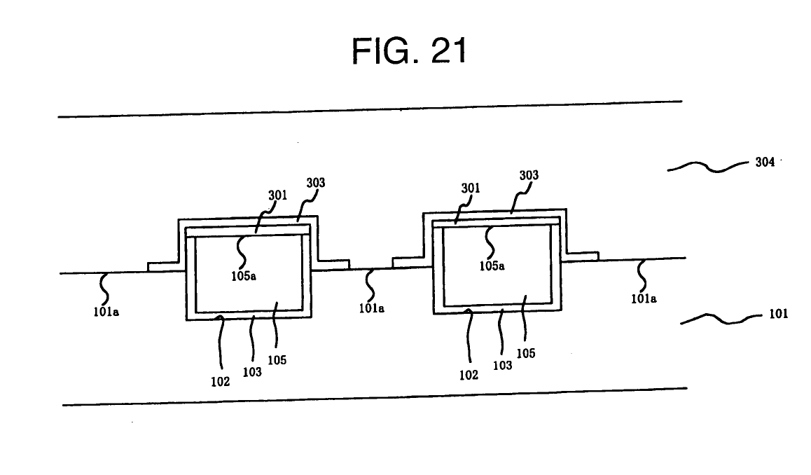

In the above embodiment, the cap films 301 are formed wider than the wiring films 105 and the barrier films 103; however, if there is not a possibility that the barrier films 103 are etched in the thinning of the insulating film 101, as shown in FIG. 21, the cap films 301 may be formed to lie only on the upper faces of the wiring films 105 and the barrier films 103. If the cap films 301 are formed only on the upper faces of the wiring films 105 and the barrier films 103, the distance between the adjoining cap films 301, that is, substantially the distance between the wirings will be expanded, which will further enhance the dielectric strength. And, there can be a case such that the cap films 301 are dislocated, and part of the upper faces of the barrier films 103 are not covered with the cap films 301; however, since they are further covered with the cap films 303, there cannot be an apprehension that the wiring films 105 are oxidized.

### (4) Fourth Embodiment

The wiring structure of a semiconductor device relating to the fourth embodiment also intends, in the same manner as the third embodiment, to enhance the dielectric strength of the wirings by preventing a diffusion of the wiring material, and to repress dispersions of the resistances of the wiring films.

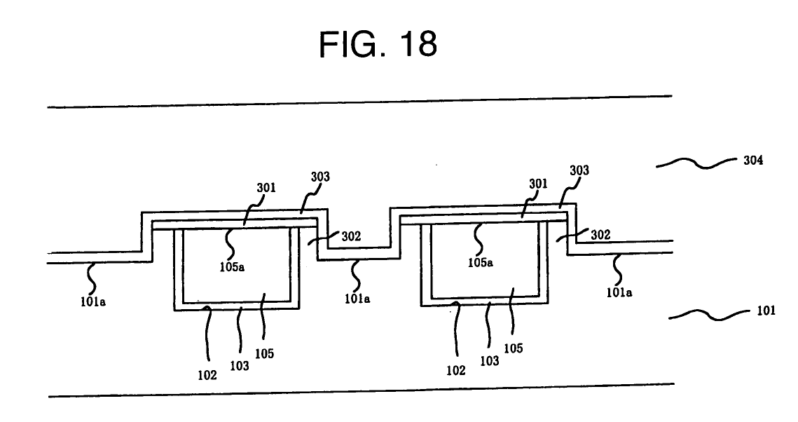

In the third embodiment, the cap films 303 are etched in the process of FIG. 16, and they are separated each by the groves 102; however, the etching of eh cap films 303 may be omitted. That is, after the process of FIG. 15, as shown in FIG. 18, the insulating film 304 of 700 nm thick, made of silicon oxide SiO₂, is deposited on the cap films 303 and the insulating film 101 by means of the CVD method.

Also in this case, since the edges of the upper faces 105a of the wiring films 105 being a leakage source of the wiring material Cu are separated in the vertical direction from the interface 101a being a path of a leakage current by the wiring material, even if the wiring material Cu is leaked from the wiring films 105, it is difficult to arrive at the interface 101a being the path of a leakage current, which restrains the wring material Cu from diffusion, and enhances the dielectric strength of the wirings.

Since the insulating film 101 is thinned in the state that the wiring films 105 are covered with the cap films 301, it is possible, in the thinning of the insulating film 101, to prevent the wiring films 105 from decreasing the volume thereof by being polished in the polishing process using the CMP method. As the result, it is possible to restrain dispersions of the resistances of the wiring films 105. And, in case of thinning the insulating film 101 through the HF processing, there is an apprehension that the films made of Ta generally used for the barrier films 103 are etched. However, in case of carrying out the etching as in this embodiment, in the state that the wiring films 105 and the barrier films 103 are covered with the cap films 301, there cannot be an apprehension that the films made of Ta are etched.

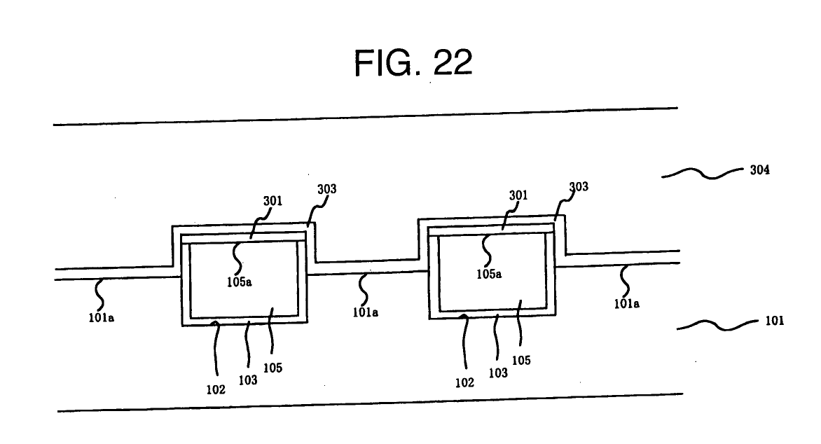

In the above embodiment, the cap films 301 are formed wider than the wiring films 105 and the barrier films 103; however, if there is not a possibility that the barrier films 103 are etched in the thinning of the insulating film 101, as shown in FIG. 22, the cap films 301 may be formed to lie only on the upper faces of the wiring films 105 and the barrier films 103. If the cap films 301 are formed only on the upper faces of the wiring films 105 and the barrier films 103, the distance between the adjoining cap films 301, that is, substantially the distance between the wirings will be expanded, which will further enhance the dielectric strength. And, there can be a case such that the cap films 301 are dislocated, and part of the upper faces of the barrier films 103 are not covered with the cap films 301; however, since they are further covered with the cap films 303, there cannot be an apprehension that the wiring films 105 are oxidized.

1. A wiring structure of a semiconductor device, comprising:
a first insulating film having plural grooves formed thereon, which has an interface in the horizontal direction between the adjoining grooves;
plural wiring films formed to protrude from the interface, each by the grooves of the first insulating film;
plural barrier films, formed on bottoms of the wiring films, which are formed on side faces of the wiring films to a height exceeding the interface; and
plural cap films formed at least on upper faces of the wiring films, which are separated each by the grooves.

2. A wiring structure of a semiconductor device as claimed in claim 1, wherein the cap films are formed on parts protruding from the interface from the upper faces of the wiring films till the interface of the first insulating film, and are separated on the interface.

3. A wiring structure of a semiconductor device as claimed in claim 2, wherein the cap films-are formed only on the upper faces of the wiring films and the barrier films.

4. A wiring structure of a semiconductor device as claimed in claim 2, wherein the cap films are an insulating film containing SiₓN_{y}, SiₓC_{y}, SiₓO_{y}N_{z}, or SiₓC_{y} as a principal composition.

5. A wiring structure of a semiconductor device as claimed in claim 2, wherein the cap films are a metal film made of TaₓN_{y}, Ta, or TaₓSi_{y}N_{z}.

6. A wiring structure of a semiconductor device as claimed in claim 2, wherein the cap films are a metal film made of TiₓN_{y} or TiₓSi_{y}N_{z}.

7. A wiring structure of a semiconductor device as claimed in claim 2, wherein the cap films are a metal film made of WₓN_{y} or WₓSi_{y}N_{z}.

8. A wiring structure of a semiconductor device as claimed in claim 1, wherein the cap films are formed selectively on parts of the wiring films and the barrier films, protruding from the interface.

9. A wiring structure of a semiconductor device as claimed in claim 1, wherein the cap films are a metal film containing tungsten W as a principal composition.

10. A wiring structure of a semiconductor device as claimed in claim 1, wherein the first insulating film has plural protrusions protruding from the interface, and the grooves are formed in the protrusions.

11. A wiring structure of a semiconductor device as claimed in claim 10, wherein the upper faces of the wiring films and the barrier films are substantially coincident with upper ends of the grooves.

12. A wiring structure of a semiconductor device as claimed in claim 11, wherein the protrusions are formed through etching the first insulating film, using the cap films as a mask, and the upper faces of the cap films have substantially the same shape with the upper faces of the protrusions.

13. A wiring structure of a semiconductor device as claimed in claim 12, wherein the cap films are a metal film made of TaₓN_{y}, Ta, or TaₓSi_{y}N_{z}.

14. A wiring structure of a semiconductor device as claimed in claim 12, wherein the cap films are a metal film made of TiₓN_{y} or TiₓSi_{y}N_{z}.

15. A wiring structure of a semiconductor device as claimed in claim 12, wherein the cap films are a metal film made of WₓN_{y} or WₓSi_{y}N_{z}.

16. A wiring structure of a semiconductor device as claimed in claim 12, wherein the cap films are an insulating film containing SiₓN_{y}, SiₓO_{y}N_{z}, SiₓC_{y}, or SiₓC_{y} as a principal composition.

17. A method of manufacturing a wiring structure of a semiconductor device, comprising the steps of:
forming plural grooves on a first insulating film;
forming barrier films and wiring films in order on the first insulating film;
flattening the wiring films and the barrier films until the first insulating film is exposed, and leaving the wiring films and the barrier films only in the grooves;
thinning the first insulating film, and protruding the wiring films and the barrier films from an interface of the first insulating film; and
after thinning the first insulating film, forming cap films separated each by the grooves.

18. A method of manufacturing a wiring structure of a semiconductor device, as claimed in claim 17, wherein the step of flattening the wiring films and the barrier films comprises the steps of:
polishing the wiring films, using the barrier films as a stopper; and
polishing the wiring films and the barrier films, using the first insulating film as a stopper.

19. A method of manufacturing a wiring structure of a semiconductor device, as claimed in claim 17, wherein the step of forming the cap films comprises the steps of:
after thinning the first insulating film, forming the cap films on a whole surface; and
removing part of the cap films between the grooves to separate the cap films each by the grooves.

20. A method of manufacturing a wiring structure of a semiconductor device, as claimed in claim 17, wherein the step of forming the cap films forms the cap films selectively on parts of the wiring films and the barrier films, protruding from the interface, to form the cap films separated each by the grooves.

21. A method of manufacturing a wiring structure of a semiconductor device, as claimed in claim 20, wherein the cap films are made of tungsten W.

22. A method of manufacturing a wiring structure of a semiconductor device, comprising the steps of:
forming plural grooves on a first insulating film;
forming barrier films and wiring films in order on the first insulating film;
flattening the wiring films and the barrier films until the first insulating film is exposed, and leaving the wiring films and the barrier films only in the grooves;
after flattening the wiring films and the barrier films, forming cap films on a whole surface;
removing the cap films so as to leave the cap films at least on the wiring films and the barrier films; and
thinning the first insulating film in parts having the cap films removed, and protruding the wiring films and the barrier films from an interface of the first insulating film of the thinned parts.

23. A method of, manufacturing a wiring structure of a semiconductor device, as claimed in claim 22, wherein the step of removing the cap films removes the cap films so as to leave the cap films only on the wiring films and the barrier films.

24. A method of manufacturing a wiring structure of a semiconductor device, as claimed in claim 22, wherein the step of flattening the wiring films and the barrier films comprises the steps of:
polishing the wiring films, using the barrier films as a stopper; and
polishing the wiring films and the barrier films, using the first insulating film as a stopper.

25. A method of manufacturing a wiring structure of a semiconductor device, as claimed in claim 22, wherein the step of thinning the first insulating film processes the first insulating film, using at least the cap films left on the wiring films and the barrier films as a mask.

26. A wiring structure of a semiconductor device, comprising:
a first insulating film having plural protrusions in which grooves are formed, which has an interface in the horizontal direction between the adjoining protrusions;
plural wiring films embedded in the grooves through barrier films;
plural first cap films formed on upper faces of the protrusions; and
second cap films formed on the first cap films and the first insulating film.

27. A wiring structure of a semiconductor device as claimed in claim 26, wherein the upper faces of the wiring films and the barrier films are substantially coincident with upper ends of the grooves.

28. A wiring structure of a semiconductor device as claimed in claim 26, wherein the protrusions are formed through etching the first insulating film, using the first cap films as a mask, and the upper faces of the first cap films have substantially the same shape with the upper faces of the protrusions.

29. A wiring structure of a semiconductor device as claimed in claim 28, wherein the first cap films are a metal film made of TaₓN_{y}, Ta, or TaₓSi_{y}N_{z}.

30. A wiring structure of a semiconductor device as claimed in claim 28, wherein the first cap films are a metal film made of TiₓN_{y} or TiₓSi_{y}N_{z}.

31. A wiring structure of a semiconductor device as claimed in claim 28, wherein the first cap films are a metal film made of WₓN_{y} or WₓSi_{y}N_{z}.

32. A wiring structure of a semiconductor device as claimed in claim 28, wherein the second cap films are an insulating film containing SiₓN_{y}, SiₓO_{y}N_{z}, SiₓC_{y}, or SiₓC_{y} as a principal composition.
